(19) United States
(12) Patent Application Publication
(10) Pub. No.: US 2013/0095650 A1
(43) Pub. Date: Apr. 18, 2013

(54) System And Method For Constructing Waffle Transistors

(71) Applicant: Tsutomu Shimomura, Incline Village, NV (US)

(72) Inventor: Tsutomu Shimomura, Incline Village, NV (US)

(73) Assignee: NEOFOCAL SYSTEMS, INC., Portland, OR (US)

(21) Appl. No.: 13/274,257

(22) Filed: Oct. 14, 2011

(51) Int. Cl. H01L 21/768; G06F 17/50

(52) U.S. Cl. 438/618; 716/126; 257/E21.59

(57) ABSTRACT

Waffle transistors are used within an integrated circuit when a transistor must carry an amount of current greater than the amount of current carried by a typical transistor in the integrated circuit. In a waffle transistor a set of source areas and drain areas are arranged in a checkerboard pattern. The source areas must all be connected together and the drain areas must all be connected together. To efficiently connect the source (or drain) areas together, a serpentine metal interconnect pattern is used. The serpentine pattern reduces the amount of metal required outside of the array. The serpentine pattern may be improved with offset contacts in the source and drain areas that cause the serpentine metal interconnects to be straighter.

### TECHNICAL FIELD

The present invention relates to the field of semiconductor integrated circuits. In particular, but not by way of limitation, the present invention discloses techniques for designing an manufacturing integrated circuit transistors designed to carry large amounts of current.

### BACKGROUND

Modern electronic devices are generally filled with integrated circuit devices. Integrated circuit devices are devices created with geometric patterns of doped semiconductor materials, insulators, and conductors that have been arranged to create useful electrical circuits.

The geometric patterns of semiconductor materials within in an integrated circuit have been doped to alter charge carrier concentration. N-type semiconductor regions are doped to increase negative charge concentration. This is performed by increasing the concentration of electrons. P-type semiconductor regions are doped to increase positive charge carrier concentration. Since electrical current is generally the movement of electrons which are negative charge carriers, the P-type semiconductor regions are created by decreasing the concentration of electrons which is generally referred to as increasing the concentration of ‘electron holes’.

The most fundamental circuits within an integrated circuit device are diodes and transistors. Diodes are generally formed with a P-N junction: a junction between P-type semiconductor material with N-type semiconductor material. Transistors may be formed with N-P-N or P-N-P type junctions. Such transistors are referred to as Bipolar Junction Transistors (BJTs). Field effect transistors (FET) are another type transistor design used within integrated circuits. Field effect transistors operate by using a gate which creates an electrical field in small channel between the drain and the source of the transistor. Due to their low noise and lower power requirements, field effect transistors (FETs) are used in most digital integrated circuits instead of Bipolar Junction Transistors (BJTs).

Field effect transistors (FETs) may be used to handle most of the transistor needs within a digital integrated circuit. However, occasionally a transistor may need to handle a larger amount of current than can be handled by a simple field effect transistor (FET). For example, connections to other external circuits outside of an integrated circuit may require larger amounts of current. To handle situations wherein more electrical current must be handled, a ‘waffle’ transistor design may be used. A waffle transistor is a large array of multiple transistors that act in parallel. Since waffle transistors are specifically designed to carry large amounts of current, waffle transistors must be carefully designed in order to minimize electromigration issues that can cause an integrated circuit to fail after substantial use.

### BRIEF DESCRIPTION OF THE DRAWINGS

In the drawings, which are not necessarily drawn to scale, like numerals describe substantially similar components throughout the several views. Like numerals having different letter suffixes represent different instances of substantially similar components. The drawings illustrate generally, by way of example, but not by way of limitation, various embodiments discussed in the present document.

FIG. 1A illustrates a small section of a waffle transistor.

FIG. 1B illustrates a pattern for a metal interconnect layer that may be used to connect the source squares and drain squares in the waffle transistor of FIG. 1A.

FIG. 1C illustrates how interconnect metal around the waffle array may be used to connect together separate diagonal metal connections in the waffle transistor of FIG. 1A.

FIG. 1D illustrates an example of a waffle transistor constructed using the teachings from FIGS. 1B and 1C.

FIG. 2 illustrates one possible method of altering the waffle transistor design of FIG. 1D by adding a second metal layer to carry current.

FIG. 3 illustrates a first embodiment of a serpentine metal wiring pattern that may be used within a waffle transistor array.

FIG. 4A illustrates a larger view of the serpentine transistor lay-out of FIG. 3 rotated 90 degrees.

FIG. 4B illustrates an alternate version of the waffle transistor illustrated in FIG. 4A.

FIG. 5A illustrates a first embodiment of the second and third metal layers that may be used for the waffle transistor of FIG. 4A.

FIG. 5B illustrates a second embodiment of the second and third metal layers that may be used for the waffle transistor of FIG. 4A.

FIG. 5C illustrates a third embodiment of the second and third metal layers that may be used for the waffle transistor of FIG. 4A.

FIG. 6 illustrates an example of a section of a waffle transistor that uses offset contacts to straight the serpentine metal interconnects.

### DETAILED DESCRIPTION

The following detailed description includes references to the accompanying drawings, which form a part of the detailed description. The drawings show illustrations in accordance with example embodiments. These embodiments, which are also referred to herein as “examples,” are described in enough detail to enable those skilled in the art to practice the invention. It will be apparent to one skilled in the art that specific details in the example embodiments are not required in order to practice the present invention. For example, although the example embodiments are mainly disclosed with reference to one particular semiconductor process technology, the teachings of this disclosure can be used with other semiconductor process technologies. The example embodiments may be combined, other embodiments may be utilized, or structural, logical and electrical changes may be made without departing from the scope what is claimed. The following detailed description is, therefore, not to be taken in a limiting sense, and the scope is defined by the appended claims and their equivalents.

In this document, the terms “a” or “an” are used, as is common in patent documents, to include one or more than one. In this document, the term “or” is used to refer to a nonexclusive or, such that “A or B” includes “A but not B,” “B but not A,” and “A and B,” unless otherwise indicated. Furthermore, all publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

Waffle Transistors

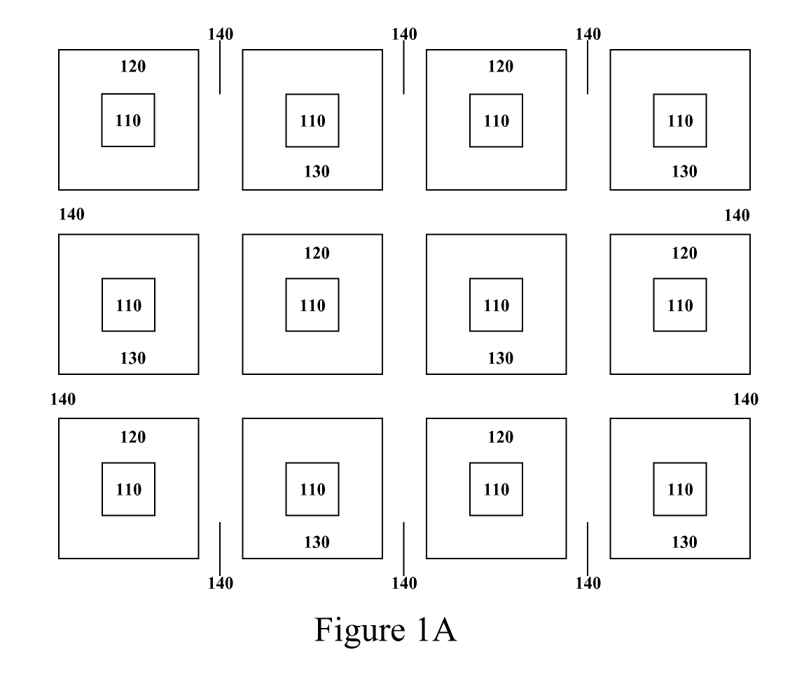

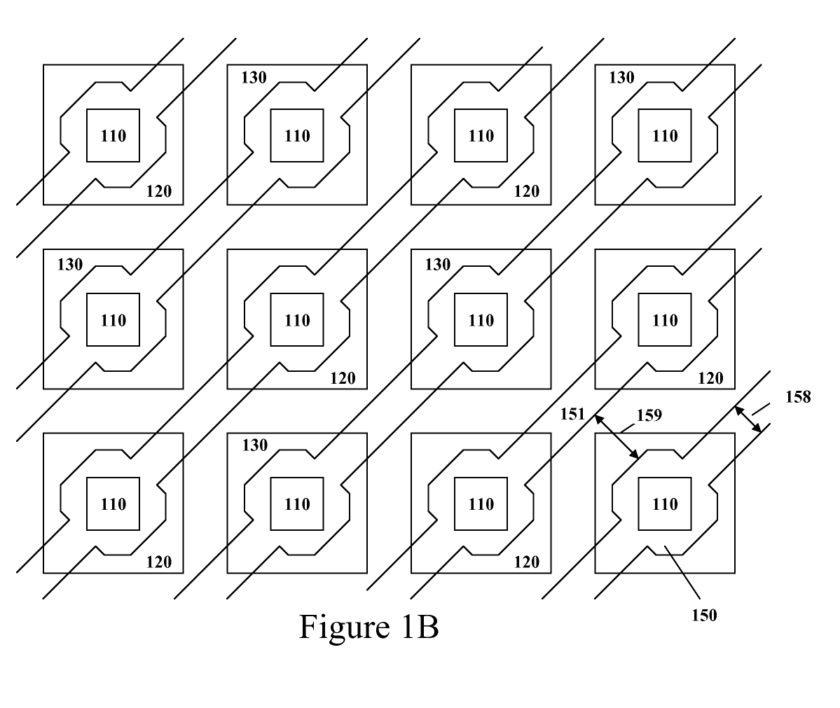

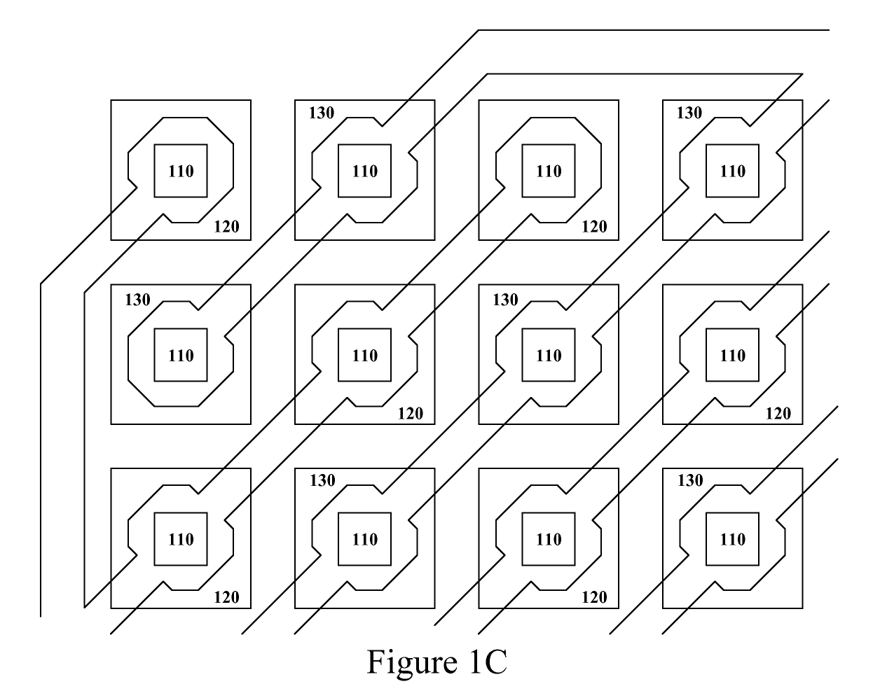

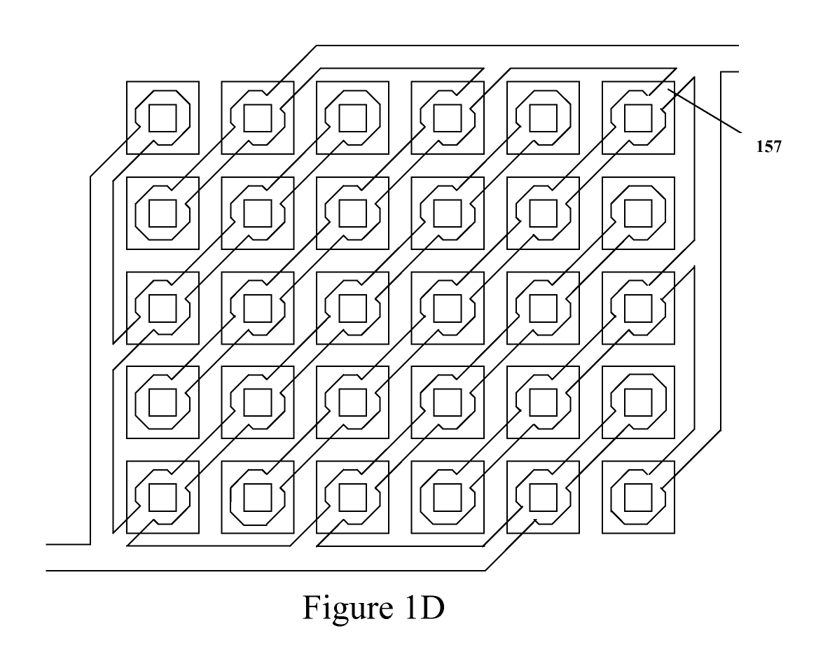

A waffle transistor is a transistor design that uses an array of sources and drains arranged in an alternating pattern. FIG. 1A illustrates a small section of a typical waffle transistor. The waffle transistor is made up of a checkerboard pattern of source squares 120 and drain squares 130. The commonly used checkerboard pattern gave rise to ‘waffle’ part of the term ‘waffle transistor’ since the checkerboard pattern appears similar to the pattern on a waffle-iron. The source squares 120 and drain squares 130 are separated by gate material 140 that forms a crosshatch lattice pattern. Each of the source squares 120 and drain squares 130 in the waffle transistor includes a contact 110 that is coupled to a metal layer used to source or sink electrical current. A control signal is provided to the gate material 140 to allow current to flow between the source squares 120 and drain squares 130.

FIG. 1B illustrates a pattern for a metal layer that may be used to connect the source squares 120 and drain squares 130. The pattern illustrated in FIG. 1B is a diagonal pattern that is commonly used in waffle transistor designs. When all of the different source squares 120 are connected then all the connected source squares 120 act as one large source region. Similarly, when all the different drain squares 130 are connected then all the connected drain squares 130 act as one large drain region. The interlaced pattern of the source squares 120 and drain squares 130 creates a very large amount of gate width between the source regions and the drains region of the waffle transistor.

All integrated circuit designs must follow a set of integrated circuit manufacturer “design rules” that limit what can be manufactured within a particular integrated circuit manufacturing process. The design rules for an integrated circuit manufacturing process present a set of integrated circuit layout restrictions that must be carefully followed in order to create an integrated circuit design that can be reliably manufactured and that will not fail during usage of the manufactured integrated circuit.

In the waffle transistor layout design of FIG. 1B, three important limitations are the minimal contact enclosure rule, the minimum metal width rule, and the minimum metal spacing rule. The minimal contact enclosure rule requires that the contact 110 be surrounded by a minimal amount of metal 150 to ensure a reliable connection between the contact 110 and the metal 150. The minimum metal width rule requires that the narrow parts of a metal conductor (such as 151 and 158) have at least a minimum width in order to reliably conduct electrical current. And the minimum metal spacing rule requires that distance (such as 159) between different metal conductors must be at least a minimum defined distance. Note that these design rules interact with each other. For example, if the metal enclosure 150 were made larger, that enlarged metal enclosure would encroach upon the distance 159 between two different metal conductors thus possibly violating the minimum metal spacing rule. Thus, integrated circuits must be carefully laid out to conform to all of the applicable design rules for a particular integrated circuit manufacturing process.

All of the separate source squares 120 in FIG. 1B must ultimately be coupled together. Similarly, all of the separate drain squares 130 must ultimately be coupled together. FIG. 1C illustrates how interconnect metal around the waffle transistor array may be used to connect together separate diagonal connections. FIG. 1D illustrates an example of a waffle transistor constructed using the teachings from FIGS. 1B and 1C. In the waffle transistor of FIG. 1D, all of the source squares and the drain squares are coupled together using wiring around the outside of the waffle array.

The waffle transistor of FIG. 1D is sufficient for some applications, however, it cannot be scaled up to large sizes. Specifically, the long diagonal runs from the lower-left of the waffle array to the upper-right of the waffle array end up carrying a large amount of current on a relatively small metal pathway. For example, the small section of metal 157 must carry all of the current for all five of the sources (or drains) that it connects to the main metal conductor for the drain (or source). If the waffle transistor of FIG. 1D were scaled up to a larger size, the long diagonal runs (such as diagonal metal 157) would ultimately fail due to electromigration issues. Specifically, too much current carried by a long narrow conductor will eventually cause that narrow conductor to fail.

Using a Second Metal Layer with a Waffle Transistor Design

In order to build a larger waffle transistor, a better method of handling the current is needed. This may be accomplished by using another layer of metal to carry current associated with the source squares and drain squares. To use another metal layer, vias in an insulating layer must be constructed to carry current between the two metal layers. Similar to the contacts 110 illustrated in FIGS. 1A to 1D, a minimum amount of metal must surround the vias between different metal layers to ensure a good connection between the two metal layers.

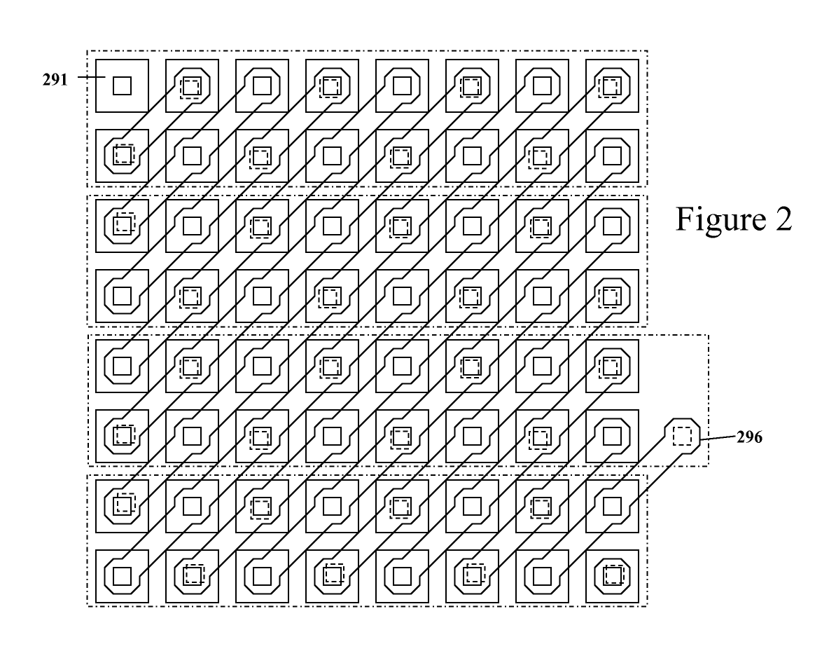

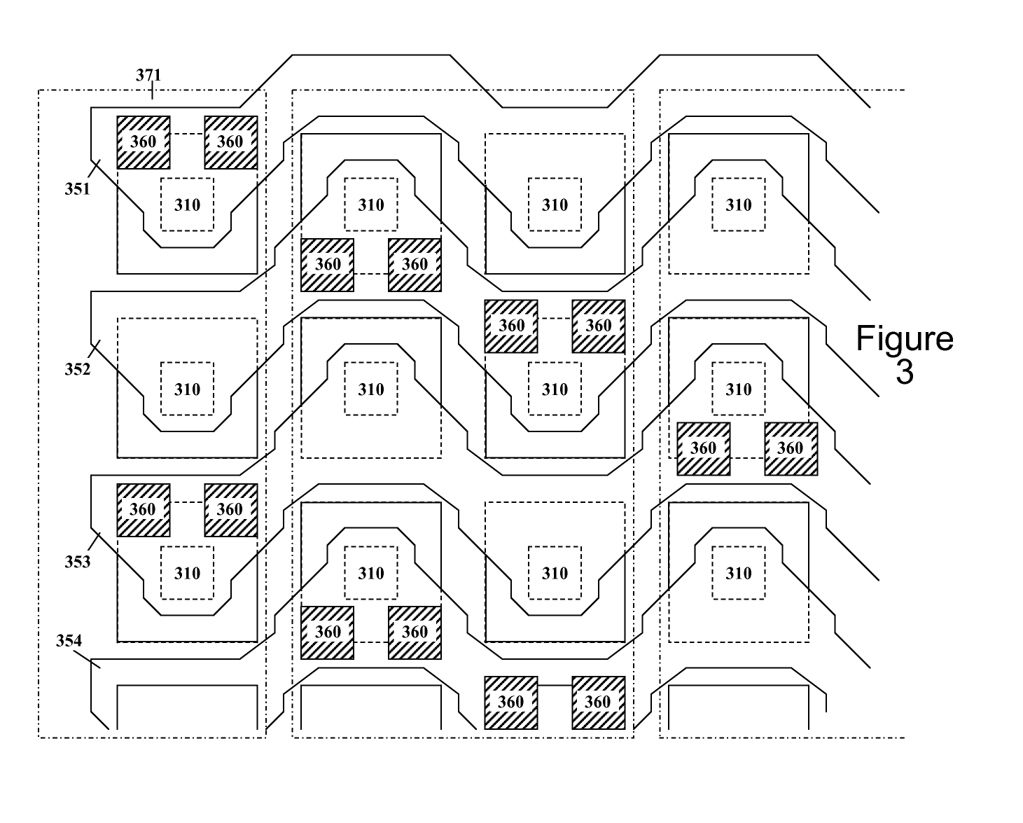

FIG. 2 illustrates one possible method of altering the waffle transistor design of FIG. 1D to use a second metal layer to carry current instead of relying on a single metal layer. In the transistor design of FIG. 2, each diagonal metal segment now includes a via (illustrated as a square drawn with a dashed line) stacked on top of the contacts for the sources/drains to another metal layer. The via is used to carry current from a first metal layer (the diagonal metal connections) to a second metal layer illustrated in FIG. 2 as large rectangles drawn with dot-dash lines. The large alternating rectangular bars of metal on the second metal layer pick up the current from the sources and drains. The waffle transistor design of FIG. 2 effectively reduces the serious electromigration problems of the long diagonal runs in the waffle transistor design of FIG. 1D by picking up current at several points along the diagonal metal runs using vias coupled to the metal bars in a second metal layer.

However, the waffle transistor layout design of FIG. 2 introduces a new problem. Specifically, one problem with the waffle transistor design of FIG. 2 is that corner sections of the waffle transistor are difficult to connect to the second metal layer. In the upper-left corner area of the waffle transistor in FIG. 2, the drain/source square 291 is left unconnected. That corner drain/source 291 can only be connected by adding additional metal on the first layer outside of the waffle transistor array. Similarly, two source/drain areas in the bottom right corner of the waffle transistor array cannot be easily connected to the second metal layer. In the example of FIG. 2, those two source/drain squares are coupled to the second metal layer by using a via 296 that extends far outside the waffle transistor array.

A Serpentine Waffle Transistor Lay-Out

To remedy the lay-out deficiencies of the traditional diagonal-wiring waffle transistors, this disclosure introduces a waffle transistor layout that uses a serpentine metal wiring pattern. The serpentine metal wiring pattern eliminates the corner problem evident in the waffle transistor design of FIG. 2. Furthermore, the serpentine metal wiring pattern groups the contact to the source/drain and the via to the second metal layer close together such that the metal enclosure rules and metal separation rules can be followed without increasing the size of the waffle transistor array.

FIG. 3 illustrates a first embodiment of a serpentine metal wiring pattern that may be used within a waffle transistor array. In the serpentine metal wiring lay-out of FIG. 3, the alternating source regions and drain regions of adjacent rows are coupled together with a serpentine (AKA zigzag) metal wiring pattern that encloses the contacts 310 to the source regions and drain regions. The metal area around the contacts 310 also encloses vias 360 that connect to a second metal layer. In the specific embodiment of FIG. 3, two vias 360 are used in close proximity due to a particular process vendor's requirement of specific sized square vias. However, the two adjacent vias 360 may be replaced by a single larger rectangular via, a larger square via, or other via shapes in other embodiments.

In the embodiment of FIG. 3, alternating parallel rows of serpentine metal couple together source regions and drain regions. For example, serpentine metal rows 351 and 353 may couple drain regions and serpentine metal rows 352 and 354 may couple source regions. The first metal layer may be coupled together using rectangular metal bars drawn with a dot-dash line on a second metal layer. For example, second metal layer metal bar 371 may couple together first metal layer serpentine metal rows 351 and 353. Note that in the particular serpentine metal wiring layout of FIG. 3 each contact (to a drain or source) is no further than two diagonal segments of wiring away from a via to the second metal layer. Thus, the serpentine metal wiring lay-out of FIG. 3 is very unlikely to have any electromigration issues in that first metal layer.

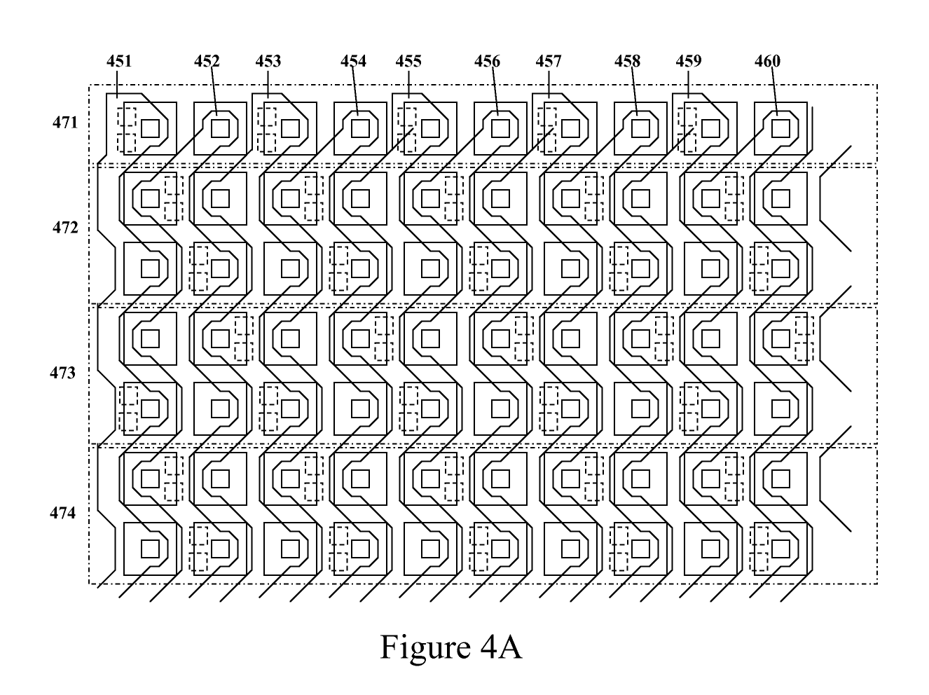

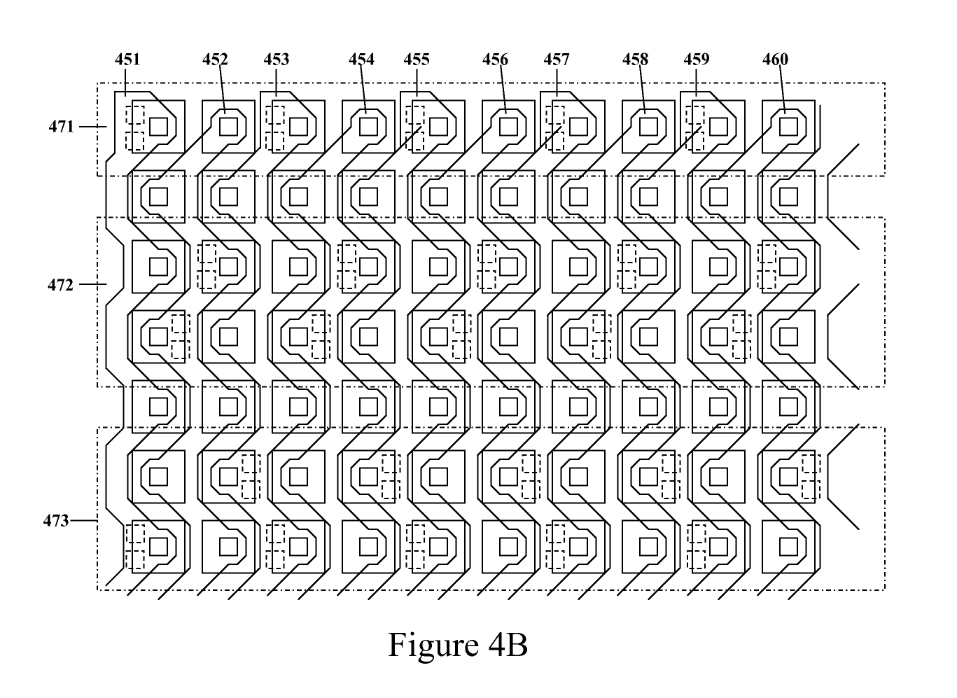

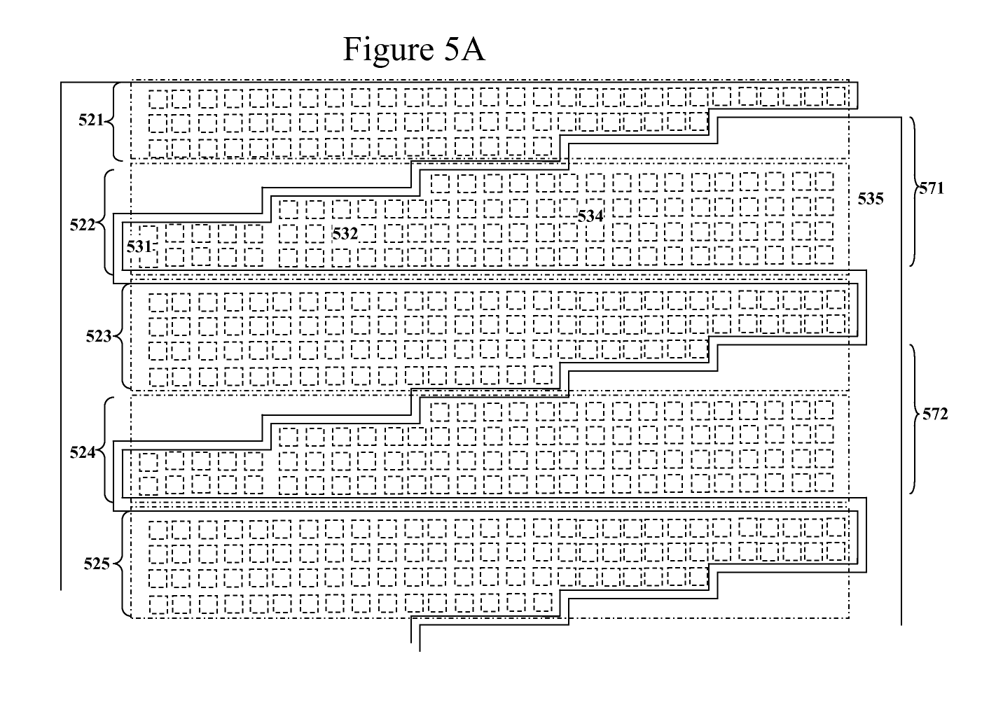

FIG. 4A illustrates a larger view of the same type of serpentine transistor layout illustrated FIG. 3 but rotated 90 degrees wherein there are columns of serpentine metal. The odd numbered serpentine metal columns (451, 453, . . . , 459) may couple together drain regions. The odd numbered serpentine metal columns are coupled to the odd numbered metal bars (471 and 473) on the second metal layer using vias. Similarly, the even numbered serpentine metal columns (452, 454, . . . , 460) may couple together source regions and are coupled to the even numbered metal bars (472 and 474) on the second metal layer using vias. Thus, as illustrated in FIG. 4A, a metal rectangle 471 connects to the vias from the end of the odd numbered serpentine metal columns (451, 453, . . . , 459). The next metal rectangle 472 connects to vias for the even numbered serpentine metal columns (452, 454, . . . , 460). And so on.

Note that with the serpentine metal layouts of FIGS. 3 and 4A, no metal is required outside of the waffle transistor array on the first metal layer except for a small amount on the left side of the array to create a slightly different truncated serpentine pattern 451 used to connect the source or drain regions on the left edge of the array. A similar truncated serpentine pattern may be placed on the right edge of the waffle transistor array (not shown).

FIG. 4B illustrates an alternate version of the waffle transistor illustrated in FIG. 4A. The waffle transistor of FIG. 4B uses rectangular metal bars in the second metal layer that skip one row of drains/sources. In the embodiment of FIG. 4B, the metal rectangles can be created wider and will have a larger amount of space between the rectangles such that minimum metal spacing rules are easier to comply with. Furthermore, the layout of FIG. 4B allows a small conductor to run between the second layer metal bars for a current tap to access a source or drain region in the middle of a waffle transistor layout for sampling purposes. Many different variations on the serpentine waffle transistor may be created.

Since waffle transistors are designed to carry relatively large amounts of current, one design goal is to maximize the amount of metal density so that there will be more metal for carrying current with the least amount of resistance. Thus, one may wish to maximize the width of the metal bars in the second metal layer to reduce the amount of non metal area in between alternating metal bars. However, the metal bars must be narrow enough such that distance current must travel on the first metal layer before encountering a via to the second layer is short enough to prevent any electromigration issues.

A Staggered Third Metal Layer in a Waffle Transistor

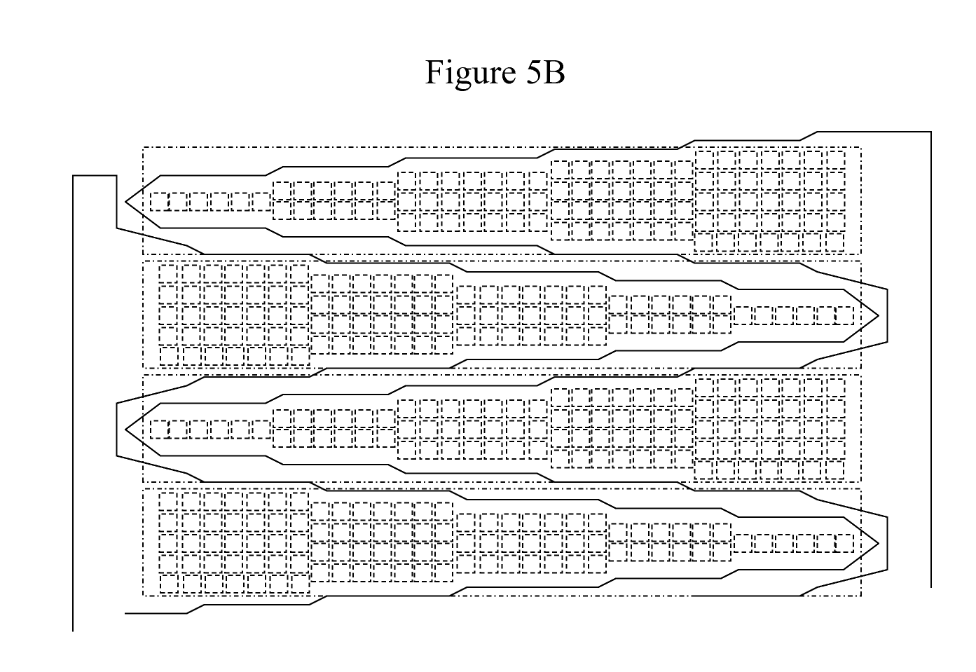

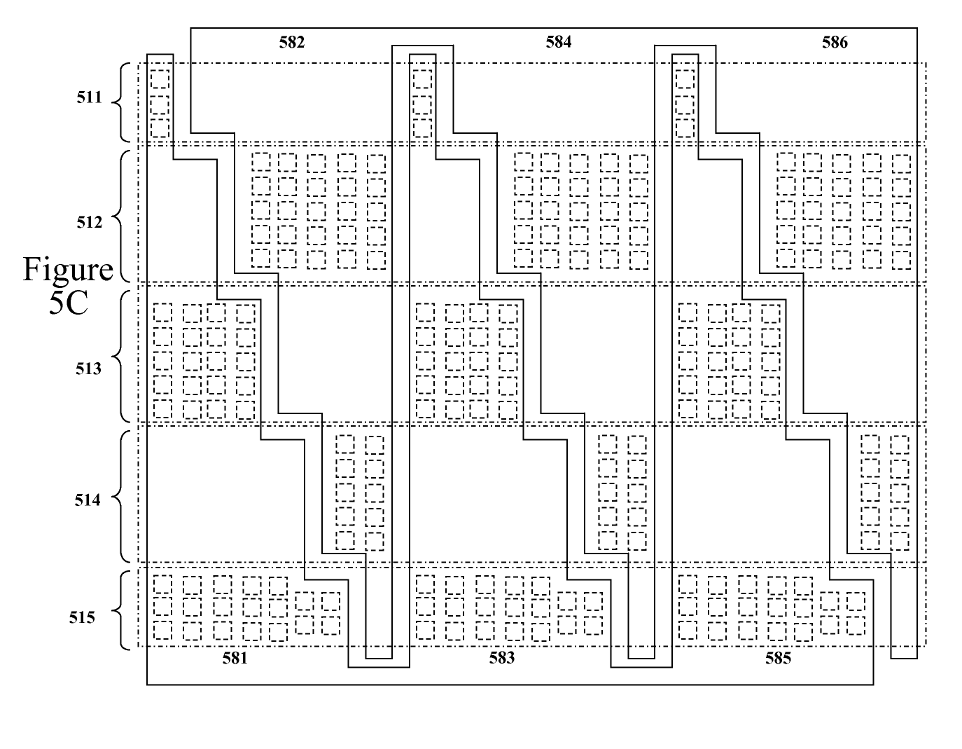

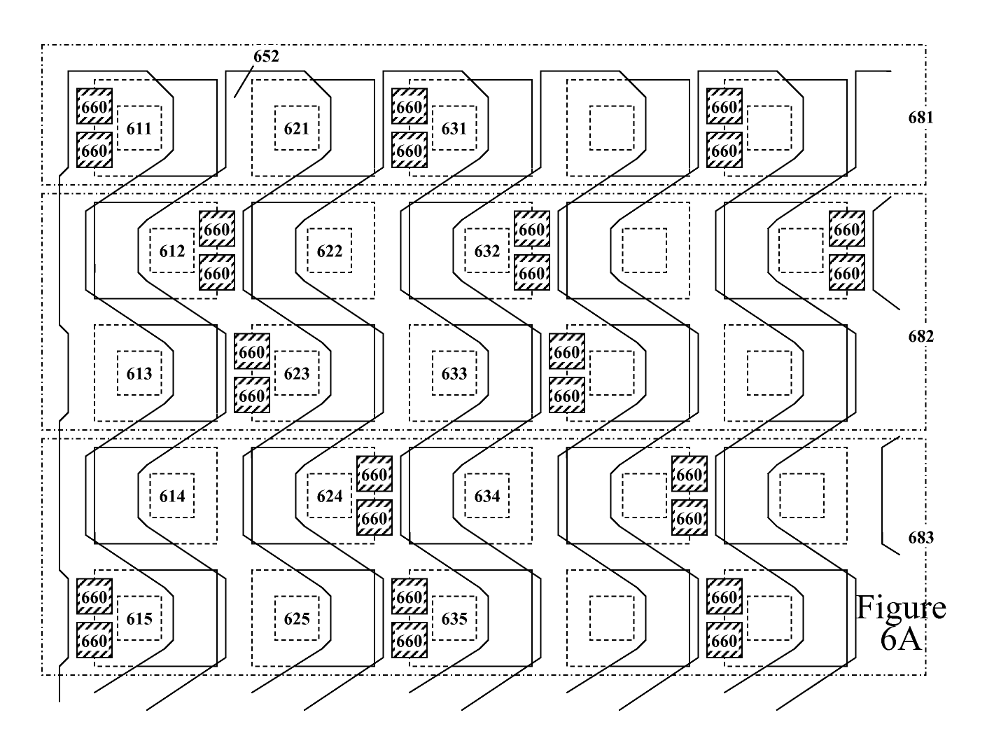

To further improve the current carrying capabilities of the waffle transistor, a third metal layer may be used. The third metal layer may be constructed in a staggered pattern such that a narrow first end picks up a small amount of current starting at one side of the waffle transistor array and the staggered metal pattern progressively becomes larger as more electrical current is picked up across the waffle transistor. A wide end carries the cumulative current for the source or drain of the waffle transistor. FIG. 5A illustrates one possible embodiment of a metal layer with such a staggered metal pattern. FIG. 5A illustrates the second and third metal layers that may be used for the waffle transistor of FIG. 4A. In FIG. 5A, the horizontal metal rectangles of the second metal layer (521, 522, 523, 524, and 525) are illustrated with dot-dash lines and the interlaced horizontal staggered patterns of the third metal layer are illustrated with solid lines. The vias that couple the second and third metal layers are drawn with squares having dashed lines. The current for the drain may be introduced at the left of the waffle transistor in FIG. 5A and the current for the source may exit out the right edge of the waffle transistor in FIG. 5A.

An example of how the staggered pattern operates will be presented with reference to a first staggered area 571 that begins as a narrow left end 531 and terminates as a wide right end 535. Starting at the left end 531 of staggered area 571, an initial amount of current is picked up from two rows of vias in area 531 that connect to a rectangular bar 522 in the second metal layer. Moving right from the narrow left-end area 531, the third layer metal becomes wider and collects more current from three rows of vias in area 532 that connect to the same rectangular bar 522 in the second metal layer. Continuing further to the right, the staggered third layer metal pattern becomes wider still and picks up more current from four rows of vias in area 534 that connect to the same rectangular bar 522 in the second metal layer. Note that since the current on this staggered metal pattern travels from left to right, all of the current coming through the vias from the second metal layer accumulates such that the total amount of current carried increases the further one travels right along staggered metal pattern 571. Finally, the staggered metal bar 571 terminates at its widest point at the right edge area 535 where the cumulative current is combined with other staggered metal patterns such as staggered metal pattern 572. As illustrated in FIG. 5A, the staggered metal patterns in the third metal layer effectively widen the conductor path as additional cumulative current is collected across the waffle transistor. At the two sides of the waffle transistor where the cumulative current is reached (the left and right sides of FIG. 5A), the source conductor and the drain conductor are at their widest.

FIG. 5B illustrates a second possible implementation of an embodiment of a metal interconnect with a staggered pattern. FIG. 5C illustrates the second and third metal layers that may be used for the waffle transistor of FIG. 4A. In the embodiment of FIG. 5C, the third metal layer uses symmetrical Christmas tree type shapes that start narrow on one end and become wide at the end where the cumulative current is collected.

FIG. 5C illustrates a third possible implementation of an embodiment of a metal interconnect with a staggered pattern. FIG. 5C illustrates the second and third metal layers that may be used for the waffle transistor of FIG. 4A. In the embodiment of FIG. 5C, the current for the drain may be introduced at the top and the current for the source may exit out the bottom. In the embodiment of FIG. 5C, the odd-numbered third layer staggered metal patterns 581, 583, and 585 couple to the odd-numbered second layer metal bars 511, 513, and 515. Similarly, the even-numbered third layer staggered metal patterns 582, 584, and 586 couple to the even-numbered second layer metal bars 512 and 514.

An example of how the staggered metal pattern operates will be presented with reference to third layer staggered metal pattern 581 for collecting drain current that is on the left side of FIG. 5C. At the top of staggered pattern 581, first amount of current is picked up from a single column of vias that connect to a first rectangular metal bar 511 in the second metal layer. The staggered pattern 581 then skips over the second rectangular bar 512 since that rectangular bar connect source regions. The staggered bar 581 then collects more current from vias connected to a third rectangular bar 513 in the second metal layer. Note that the staggered pattern 581 is wider above metal bar 513 since it is now carrying current picked up from both rectangular bar 511 and rectangular bar 513. The staggered pattern 581 then skips over the rectangular bar 514 since that rectangular bar connect source regions. Finally, the staggered bar 581 collects even more current from the vias connected to a fifth rectangular bar 515 in the second metal layer. At this point the staggered bar 581 is very wide since it is now carrying current from second metal layer rectangular bar 511, 513, and 515. Staggered bar 581 is also coupled to companion staggered bars 583 and 585 at the bottom wherein the cumulative drain current may be accessed.

A Waffle Transistor with Offset Contacts (“Wobble” Transistor Array)

To further improve the serpentine wiring pattern and increase the density of the transistor, the contacts within the source areas and drain areas may be offset from the center location to widen area for laying out the serpentine metal pattern. Specifically, with a proper offset pattern, the contacts that need to be coupled together are offset in order to be closer to each other and contacts that must be avoided are moved further apart in order to free up some space. This offset pattern effectively allows the gate width of the transistor to increase such that the transistor can carry more current. Since the contacts are offset from the center of each region, the contacts of adjacent transistor source regions and drain regions do not align with each other such that this pattern has been referred to as a “wobble” waffle transistor layout pattern.

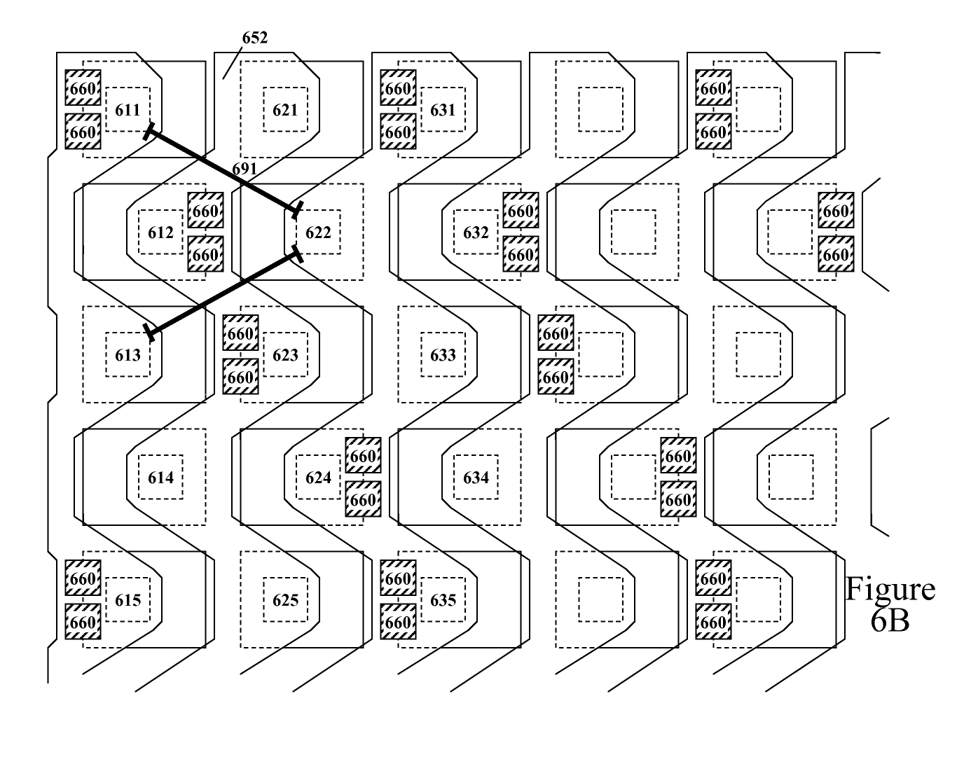

FIG. 6A illustrates an example of a section of a wobble waffle transistor that uses contacts which are offset-from-center in order to move contacts that must be coupled together closer to each other while widening a path for the serpentine metal interconnects. Note that the rectangular shape of source and drain elements. The rectangular shape increases the gate width per unit area. Serpentine metal pattern 652 connects source regions in the first column of the waffle transistor array to source regions in the second column of the waffle transistor array. To reduce the distance between the source contacts that must be coupled, the contacts in the source areas of the first column (contacts 612 and 614) have been shifted to the right and the contacts in the source areas of the second column (contacts 621, 623 and 625) have been shifted to the left. This allows the serpentine interconnect metal 652 to be straighter and shorter thus simplifying the serpentine metal layout of the first metal layer. For example, the distance between offset contact 621 and offset contact 612 is shorter than if contacts 621 and 612 had each been placed directly into the center of their respective rectangular source areas.

The serpentine metal interconnects in the first metal layer of FIG. 6A are coupled to the metal bars 681, 682, and 683 of the second layer using vias 660. Note that although the vias 660 in this particular implementation are a pair of squares, other via shapes and sizes may be used.

In addition to shortening the distance between contacts that must be coupled together, offsetting contacts may also increase the distance from contacts that must be avoided by a serpentine metal pattern. FIG. 6B illustrates the waffle transistor design of FIG. 6A, with a distance between a drain contact 611 and drain contact 622 labelled distance 691. The serpentine metal 652 that couples source contact 621 and source contact 612 must pass through the gap 691 between a drain contact 611 and drain contact 622. Since drain contact 611 in the first column has been moved to the left and drain contact 622 in the second column has been moved to the right, the gap 691 has been made wider such that the serpentine interconnect metal 652 itself may be wider and can thus carry current more efficiently. Thus, the “wobble” waffle transistor pattern of FIGS. 6A and 6B allows the serpentine metal interconnects to be shorter and wider thus improving conduction of current in the first metal layer and increasing the density of the transistor thus allowing it to carry current more efficiently. Furthermore, the rectangular shape of the source and drain regions

The waffle transistor designs illustrated in FIGS. 3 to 6B illustrate improved waffle transistor layouts that use serpentine metal interconnects in order to provide improved performance. The serpentine metal layouts are able to connect all of the source areas and drain areas in an easy and consistent manner. Furthermore, the serpentine metal layouts increase the metal density in manner such that current is conducted more efficiently. The more efficient current conduction provides several benefits. One significant benefit is that the integrated circuit is less likely to suffer a failure due to electromigration problems. Another significant benefit is that the improved conductors provide greater resistance to damage from an electro-static discharge (ESD) since the improved conductors spread the electro-static discharge event across a wider area.

The preceding technical disclosure is intended to be illustrative, and not restrictive. For example, the above-described embodiments (or one or more aspects thereof) may be used in combination with each other. Other embodiments will be apparent to those skilled in the art integrated circuits upon reviewing the above description. The scope of the claims should, therefore, be determined with reference to the appended claims, along with the full scope of equivalents to which such claims are entitled. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The Abstract is provided to comply with 37 C.F.R. §1.72(b), which requires that it allow the reader to quickly ascertain the nature of the technical disclosure. The abstract is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment.

The current claims in the above-identified patent application are as follows:

1. A transistor circuit design for use in an integrated circuit, said transistor circuit design comprising:
a grid array comprising rows and columns, said grid array comprising a set of source areas and a set of drain areas arranged in an alternating pattern;
a first set of parallel serpentine metal interconnects formed in a first metal layer, said first set of parallel serpentine interconnects coupling together transistor source areas in adjacent rows of said grid array; and
a second set of parallel serpentine metal interconnects formed in said first metal layer, said second set of parallel serpentine interconnects coupling together transistor drain areas in adjacent rows of said grid array.

2. The transistor circuit design as set forth in claim 1, said transistor circuit design further comprising:
an end serpentine metal interconnect, said end serpentine metal interconnect coupling together transistor source areas on an end row of said grid array.

3. The transistor circuit design as set forth in claim 1, said transistor circuit design further comprising:
an end serpentine metal interconnect, said end serpentine metal interconnect coupling together transistor drain areas on an end row of said grid array.

4. The transistor circuit design as set forth in claim 1, said transistor circuit design further comprising:
a first set of parallel metal interconnects formed in a second metal layer, said first set of parallel interconnects coupling together said first set of parallel serpentine metal interconnects; and
a second set of parallel metal interconnects formed in said second metal layer, said second set of parallel interconnects coupling together said second set of parallel serpentine metal interconnects.

5. The transistor circuit design as set forth in claim 4, said transistor circuit design further comprising:
a first set of staggered metal interconnects formed in a third metal layer, said first set of staggered interconnects coupling together said first set of parallel interconnects of said second layer; and
a second set of staggered metal interconnects formed in said third metal layer, said third set of staggered interconnects coupling together said second set of parallel metal interconnects.

6. The transistor circuit design as set forth in claim 5 wherein said staggered metal interconnects are narrow at a first end that picks an initial amount of current and larger at a second end that carries a cumulative amount of current larger than said initial amount of current.

7. The transistor circuit design as set forth in claim 1 wherein said transistor circuit design is for field-effect transistors.

8. (canceled)

9. (canceled)

10. (canceled)

11. (canceled)

12. (canceled)

13. (canceled)

14. (canceled)

15. A transistor circuit design for use in an integrated circuit, said transistor circuit design comprising:
a grid array comprising rows and columns, said grid array comprising a set of source areas and a set of drain areas arranged in an alternating pattern;
a first set of parallel serpentine metal interconnects formed in a first metal layer, said first set of parallel serpentine interconnects coupling together contacts in said source areas in adjacent rows, said source contacts are offset from the center of said source areas; and
a second set of parallel serpentine metal interconnects formed in said first metal layer, said second set of parallel serpentine interconnects coupling together contacts in said drain areas in adjacent rows, said drain contacts are offset from the center of said drain areas.

16. The transistor circuit design as set forth in claim 15, said transistor circuit design further comprising:
a first set of parallel metal interconnects formed in a second metal layer, said first set of parallel interconnects coupling together said first set of parallel serpentine metal interconnects; and
a second set of parallel metal interconnects formed in said second metal layer, said second set of parallel interconnects coupling together said second set of parallel metal interconnects.

17. The transistor circuit design as set forth in claim 16, said transistor circuit design further comprising:
a first set of staggered metal interconnects formed in a third metal layer, said first set of staggered interconnects coupling together said first set of parallel interconnects of said second layer; and
a second set of staggered metal interconnects formed in said third metal layer, said third set of staggered interconnects coupling together said second set of parallel metal interconnects.

18. The transistor circuit design as set forth in claim 17 wherein said staggered metal interconnects are narrow at a first end that picks an initial amount of current and larger at a second end that carries a cumulative amount of current larger than said initial amount of current.

19. (canceled)

20. (canceled)

21. (canceled)
